(19) United States
(12) Patent Application Publication
(10) Pub. No.: US 2026/0314323 A1
(43) Pub. Date: Oct. 8, 2026

(54) SYNCHRONIZED MULTI-ARM ROBOT

(71) Applicant: TOKYO ELECTRON LIMITED, Tokyo (JP)

(72) Inventor: Joshua HOOGE, Austin, TX (US)

(73) Assignee: TOKYO ELECTRON LIMITED, Tokyo (JP)

(21) Appl. No.: 19/172,337

(22) Filed: Apr. 7, 2025

(51) Int. Cl. H01L 21/687; B65G 47/90

(52) U.S. Cl. CPC H10P 72/7602; B65G 47/905

(57) ABSTRACT

A robot transfer system includes a robot arm adapted for rotation and movement. The robot arm includes multiple end effectors positioned vertically over each other, each adapted to collect, hold and deposit a respective wafer. A vertical separation system is adapted to move the end effectors vertically to adjust a vertical separation of the end effectors. A controller is configured to move the robot arm to a first location, cause the vertical separation system to position the multiple end effectors to match a first vertical separation of multiple wafers at the first location, simultaneously collect the multiple wafers, move the multiple wafers to a second location, cause the vertical separation system to position the multiple end effectors to match a second vertical separation of the multiple wafers at the second location, and cause the robot arm to simultaneously deposit the multiple wafers at the second location.

### INCORPORATION BY REFERENCE

Aspects of the present disclosure are related to Applicant's issued U.S. Pat. No. 10,475,657 and Applicant's patent publications US 2020/0083080A1 and US 2023/0326767A1, all of which are incorporated herein by reference in their entirety.

### FIELD OF THE INVENTION

This disclosure relates generally to systems and methods of semiconductor fabrication and particularly to systems and methods of batched wafer transfer and processing.

### BACKGROUND

In the manufacture of a semiconductor device (especially on the microscopic scale), various fabrication processes are executed such as film-forming depositions, etch mask creation, patterning, material etching and removal, and doping treatments. These processes are performed in various combinations to form desired semiconductor device elements on substrates that need to be transferred from one processing module to another between fabrication processes.

### SUMMARY

The present disclosure relates to a robot transfer system, a wafer processing system and a method of wafer processing.

According to some aspects of the disclosure, a robot transfer system is provided. The robot transfer system includes a robot arm adapted for rotation within the wafer processing system and adapted for movement in multiple directions within the wafer processing system. The robot arm includes multiple end effectors positioned vertically over each other. Each end effector is adapted to collect, hold and deposit a respective wafer for transfer within the wafer processing system. The robot transfer system also includes a vertical separation system adapted to move the end effectors of the robot arm vertically relative to each other to increase and decrease a vertical separation of the end effectors relative to each other. The robot transfer system further includes a controller configured to control the robot arm and control the vertical separation system. The controller is configured to move the robot arm to a first location for collecting multiple wafers separated vertically at a first spacing. The controller is configured to cause the vertical separation system to position the multiple end effectors to match a first vertical separation of the multiple wafers at the first location and simultaneously collect the multiple wafers at the first location. The controller is configured to move the multiple wafers to a second location for depositing the multiple wafers such that the multiple wafers are vertically separated relative to each other at a second spacing that is different than the first spacing. The controller is configured to cause the vertical separation system to position the multiple end effectors to match a second vertical separation of the multiple wafers at the second location and cause the robot arm to simultaneously deposit the multiple wafers at the second location.

In some embodiments, the controller is configured to cause the vertical separation system to position the multiple end effectors to match the second vertical separation of the multiple wafers simultaneously while moving the multiple wafers from the first location to the second location.

In some embodiments, the robot arm further includes multiple sliding structures. Each sliding structure connects a respective end effector to the vertical separation system and is adapted for horizontal movement to adjust a respective horizontal distance between the respective end effector and the vertical separation system.

In some embodiments, the controller is configured to horizontally move the multiple sliding structures to move the multiple end effectors towards the multiple wafers at the first location, vertically raise the multiple end effectors to simultaneously pick up the multiple wafers and horizontally move the multiple sliding structures to move the multiple end effectors towards the vertical separation system.

In some embodiments, the controller is configured to horizontally move the multiple sliding structures to move the multiple end effectors towards the second location, vertically lower the multiple end effectors to simultaneously drop off the multiple wafers and horizontally move the multiple sliding structures to move the multiple end effectors towards the vertical separation system.

In some embodiments, the robot arm includes a main body, and the vertical separation system is attached to a side surface of the main body and adapted for vertical movement along the side surface of the main body.

In some embodiments, the multiple end effectors are attached to the vertical separation system so that when the vertical separation system moves vertically along the side surface of the main body, the multiple end effectors simultaneously move vertically.

In some embodiments, after causing the vertical separation system to position the multiple end effectors to match the second vertical separation of the multiple wafers, the controller is configured to lock the multiple end effectors to the vertical separation system.

In some embodiments, the controller is configured to simultaneously move the multiple end effectors vertically by moving the vertical separation system vertically when the multiple end effectors are locked to the vertical separation system.

In some embodiments, the controller is configured to simultaneously collect or deposit the multiple wafers by moving the vertical separation system vertically when the multiple end effectors are locked to the vertical separation system.

In some embodiments, the multiple end effectors are aligned with each other vertically.

In some embodiments, the multiple end effectors include at least one of a fork structure, a semi-circle structure or a pincette.

In some embodiments, the multiple end effectors each includes a respective gas channel configured to discharge a gas or generate vacuum.

In some embodiments, the vertical separation system includes at least one of a sliding track, a linear guide or a telescopic mechanism.

In some embodiments, a wafer processing system is provided. The wafer processing system includes a robot transfer system that includes a robot arm adapted for rotation within the wafer processing system and adapted for movement in multiple directions within the wafer processing system. The robot arm includes multiple end effectors positioned vertically over each other. Each end effector is adapted to collect, hold and deposit a respective wafer for transfer within the wafer processing system. The robot transfer system also includes a vertical separation system adapted to move the end effectors of the robot arm vertically relative to each other to increase and decrease a vertical separation of the end effectors relative to each other. The robot transfer system further includes a controller configured to control the robot arm and control the vertical separation system. The controller is configured to move the robot arm to a first location for collecting multiple wafers separated vertically at a first spacing. The controller is configured to cause the vertical separation system to position the multiple end effectors to match a first vertical separation of the multiple wafers at the first location and simultaneously collect the multiple wafers at the first location. The controller is configured to move the multiple wafers to a second location for depositing the multiple wafers such that the multiple wafers are vertically separated relative to each other at a second spacing that is different than the first spacing. The controller is configured to cause the vertical separation system to position the multiple end effectors to match a second vertical separation of the multiple wafers at the second location and cause the robot arm to simultaneously deposit the multiple wafers at the second location. The wafer processing system also includes at least one wafer module including wafer mounting structures stacked vertically at the second location.

In some embodiments, the at least one wafer module includes at least one selected from the group consisting of a storage module, a metrology module, a deposition module, a coating module, a bake module, an imaging module, a development module, an etching module, a cleaning module and an inspection module.

In some embodiments, the at least one wafer module includes a deposition module including a deposition chamber and gas inlets stacked vertically and configured to deliver vapors into the deposition chamber.

In some embodiments, the wafer processing system further includes a coating module including spin coaters stacked vertically and a bake module including hot plates stacked vertically.

In some embodiments, the number of the multiple end effectors is N. The number of the wafer mounting structures is B. N is an integer of 2 or more. B is an integer of 2 or more. N is equal to or larger than B.

In some embodiments, N is a multiple of B.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a plan view of an apparatus in accordance with some embodiments of the present disclosure.

FIG. 1B shows a perspective view of an apparatus in accordance with some embodiments of the present disclosure.

FIG. 2A shows a vertical cross-sectional view of a transfer robot in accordance with some embodiments of the present disclosure.

FIG. 2B shows a top view of a transfer robot in accordance with one embodiment of the present disclosure.

FIG. 3A shows a vertical cross-sectional view of a wafer module in accordance with some embodiments of the present disclosure.

FIG. 3B shows a vertical cross-sectional view of a wafer module in accordance with some embodiments of the present disclosure.

FIGS. 4A, 4B, 4C, and 4D show vertical cross-sectional views of an apparatus at various intermediate steps of a wafer process in accordance with some embodiments of the present disclosure.

FIG. 5 shows a flow chart of a process for manufacturing a semiconductor device, in accordance with some embodiments of the present disclosure.

FIGS. 6A, 6B, 6C, 6D, 6E, 6F, 6G, 6H and 6I show vertical cross-sectional views of an apparatus at various intermediate steps of a wafer process in accordance with some embodiments of the present disclosure.

FIG. 7 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to”, “from... to...”, “-” and similar terms includes numerical values at both ends, unless specified otherwise.

The semiconductor manufacturing industry is constantly evolving, which demands greater yield despite increased complexity. More specifically, in the processing of substrates for forming integrated circuits, it has become more and more critical to increase yield and increase the efficiency and throughput in the fabrication process. Conventional fabrication protocols entail constant removal of substrates from platforms, such as systems with deposition modules, and the transport of substrates to other platforms, such as systems with etch modules or some other processing modules. Since fabrication involves large sequences of various deposition and etch and other processing steps, the need to remove substrates from a system, transport the substrates and reintroduce the substrates into another system inevitably incurs additional time and cost. The removal-transport-reintroduction processes only exacerbate the time and cost for the overall fabrication process.

The semiconductor industry has an aggressive throughput roadmap e.g.>500 wafers per hour (wph) that cannot be met with incremental improvement to even state-of-the-art design. Stacking modules can maintain the footprint and improve throughput, but can cause a track system to be robot-limited.

Techniques herein provide a multi-arm lithography track robot design in which robot arms are configured to receive and deliver multiple wafers synchronously, increasing the productivity of the robot arms. For example, robot arms can pick up two or more wafers simultaneously, and then the robot arms turn to face subsequent modules while adjusting z-separation distance between pincettes to match z distance between the subsequent modules. As a result, robot arm throughput can be multiplied to service additional vertical modules and enable e.g. a 550 wph target. Such a design applies to both carrier and process arms and can also enable batch processing units to be built into a track system. The track system can be re-designed to have processing modules that exist in multiples of the number of the robot arms. In other words, processing steps can be batched without negative impact to control or defectivity, so large improvements to productivity are possible. Robot arms can pick up two or more wafers at the same time so the robot can support more stacked modules.

Techniques herein provide a wafer processing apparatus that includes a plurality of wafer modules and a transfer module. The transfer module includes a main body and a base structure that is attached to the main body and configured to move along the main body vertically. The transfer module also includes arm structures that are attached to the base structure and stacked over each other vertically. The arm structures each include a respective pincette structure at a respective end. Each wafer module includes wafer mounting structures stacked over each other vertically. The transfer module is configured to transfer wafers from a first wafer module to a second wafer module by unloading each of the wafers from first wafer mounting structures of the first wafer module to a respective pincette structure and then placing the wafers on second wafer mounting structures of the second wafer module.

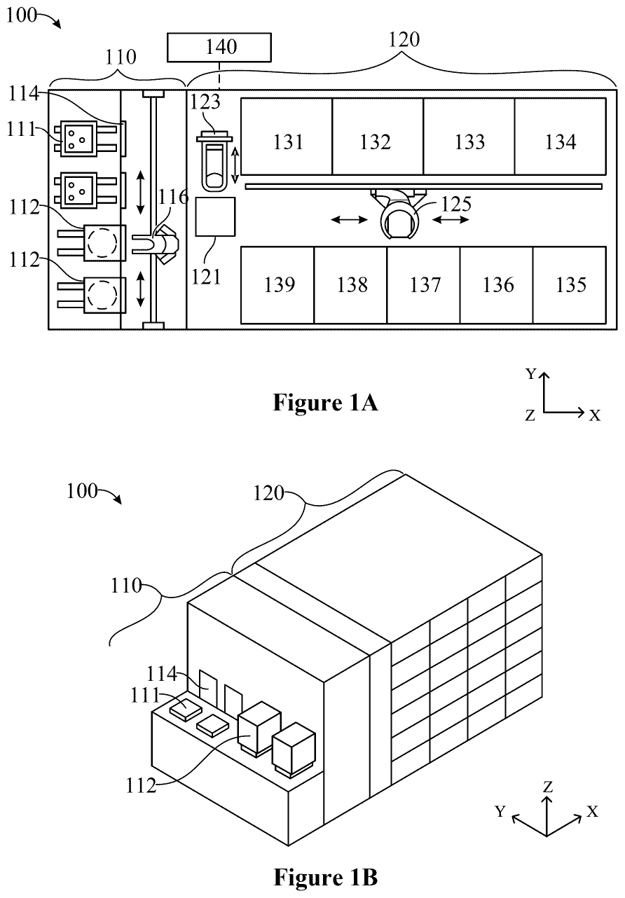

FIGS. 1A and 1B respectively show a plan view and a perspective view of an apparatus 100 (or a system, or a track system) in accordance with some embodiments of the present disclosure. In general, the apparatus 100 can include various wafer handling components and/or carriers. A carrier block 110 includes stages 111 for receiving wafer carriers 112. The wafer carriers 112 can house several (semiconductor) wafers or substrates. A door 114 can open to access the several wafers in the wafer carriers 112. A first transfer arm 116 can transfer substrates from the wafer carriers 112 to a shelf unit 121 in a treatment block 120. A second transfer arm 123 can be positioned adjacent to the shelf unit 121 and capable of moving back and forth as well as vertically. A third transfer arm 125 can access substrates, from the shelf unit 121 or the second transfer arm 123, to move among modules 131, 132, 133, 134, 135, 136, 137, 138 and 139. In a non-limiting example, the modules 131-139 can include a metrology module 131, a deposition module 132, a coating module 133, a bake module 134, an imaging module 135, a development module 136, an etching module 137, a cleaning module 138 and an inspection module 139. Additionally, the shelf unit 121 can include a FOUP (Front Opening Unified Pod or Front Opening Universal Pod), a wafer cassette or the like and optionally a chamber to house the FOUP therein and thus may be referred to as a wafer storage module.

In some embodiments, the metrology module 131 can be configured to measure wafer data such as electrical, physical and/or chemical properties of a wafer and include various characterization tools such as an optical microscope, a scanning electron microscope, an ellipsometer, a four-point probe, X-ray techniques, etc. The deposition module 132 can be configured to deposit one or more films on a backside surface of a substrate or on a front side working surface of the substrate. The coating module 133 can be configured to coat the backside surface of the substrate or the front side working surface of the substrate with a radiation-sensitive material, such as a photoresist. The bake module 134 can be configured to bake the radiation-sensitive material. The imaging module 135 can be configured to expose the radiation-sensitive material to a pattern of actinic radiation. The development module 136 can be configured to develop the radiation-sensitive material after exposure or imaging. The etching module 137 can be configured to use plasma or vapor-phase etching or wet etching. The cleaning module 138 can be configured to remove remaining (or residual) radiation-sensitive material from the substrate after an etching operation. The inspection module 139 can be configured to inspect for defects after wafer cleaning. Note that provided herein is merely a brief description of the modules 131-139 for illustrative purposes. Detailed descriptions and examples of the modules 131-139 can be found in Applicant's issued U.S. Pat. No. 10,475,657, which is incorporated herein by reference in its entirety. More descriptions and examples of modules and apparatuses can be found in Applicant's patent publications US2020/0083080A1 and US2023/0326767A1, both of which are incorporated herein by reference in their entirety.

While shown to include all of the modules 131-139 in the example of FIG. 1A, the apparatus 100 may only include one or more of the modules 131-139, depending on specific design needs in other examples. In one embodiment, the apparatus 100 may include modules 131-138 without the inspection module 139. In another embodiment, the apparatus 100 may include modules 131-135 without modules 136-139. In yet another embodiment, the apparatus 100 may include modules 132-134 without modules 131 or 135-139. Note that an external or outside tool may be used in lieu of at least one of the modules 131-139. In some examples, wafer metrology is performed in an outside metrology tool so that the metrology module 131 is not needed. In some embodiments, film formation is executed in an external or outside deposition tool so that the deposition module 132 and/or the coating module 133 are not needed. Additionally, for a given module of the modules 131-139, the apparatus 100 may include any number of the given module. For instance, the apparatus 100 may include three deposition modules 132 consisting of a chemical vapor deposition (CVD) module, a physical vapor deposition (PVD) module and an atomic layer deposition (ALD) module. Similarly, the apparatus 100 may include two etching modules 137 consisting of a dry etching module and a wet etching module. Additionally, relative positions and sizes of the modules 131-139 are not particularly limited. The second transfer arm 123 and the third transfer arm 125 may not be both needed; that is, the apparatus 100 may include only one transfer arm. While shown to be distributed in the XY plane in the example of FIG. 1A, various components and/or modules can be stacked in the Z direction for footprint reduction purposes. Accordingly, transfer arms (e.g. 116, 123 and 125) can move in all directions (e.g. X, Y, Z and theta (angular) directions).

Still referring to FIG. 1A, a controller 140 can be connected to or included by the apparatus 100. The controller 140 can be a computer processor located within the apparatus 100 or located remotely but in communication with components of the apparatus 100.

In some embodiments, the controller 140 may be coupled to various components (e.g. modules) of the apparatus 100 to receive inputs from and provide outputs to the various components. For example, the controller 140 can be configured to control at least one module selected from the group consisting of the modules 131-139. Particularly, the controller 140 can be configured to receive wafer data from the metrology module 131. The controller 140 can also be configured to adjust knobs and control settings for the deposition module 132. Further, it should be understood that one or more of the functions described herein of the controller 140 can be implemented manually. For instance, knob adjustments to the deposition module 132 can be manually made.

Additionally, components of the apparatus 100 can be connected to and controlled by the controller 140 that may optionally be connected to a corresponding memory storage unit and user interface (all not shown). Various module operations can be executed via the user interface, and various processing recipes and operations can be stored in a storage unit. Accordingly, a given substrate can be processed within the apparatus 100 with various microfabrication techniques.

The controller 140 can be implemented in a wide variety of manners. In one example, the controller 140 is a computer. In another example, the controller 140 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

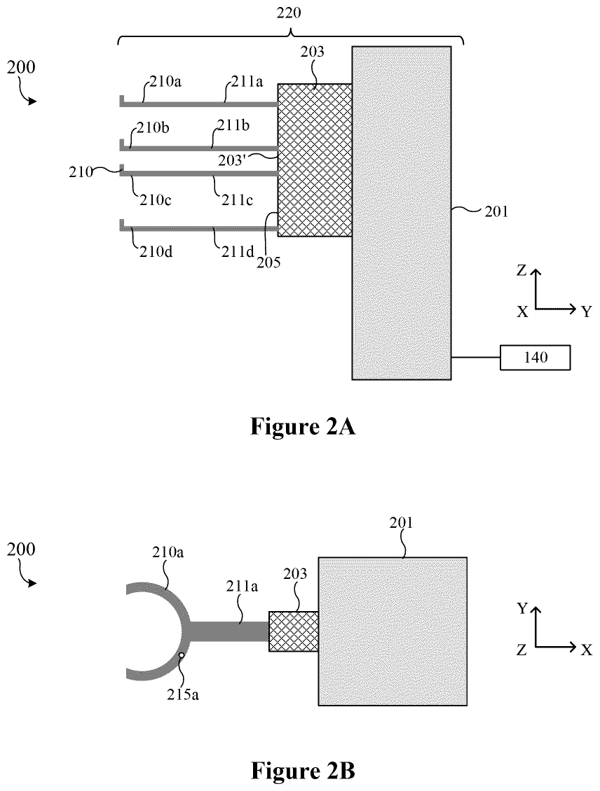

FIG. 2A shows a vertical cross-sectional view of a transfer robot 200 (also referred to as a transfer module), and FIG. 2B shows a top view of the transfer robot 200, in accordance with some embodiments of the present disclosure. Note that the transfer robot 200 herein can represent some embodiments of the second transfer arm 123 and/or the third transfer arm 125 in FIG. 1A.

As illustrated, the transfer robot 200 includes a robot arm 220 having a main body 201. A vertical separation system 203 can be attached to the main body 201 and configured to move along the main body in a vertical direction e.g. the Z direction. End effectors 210 (e.g. 210a, 210b, 210c and 210d) are attached to the vertical separation system 203 and stacked over each other in the Z direction.

The end effectors 210 are attached to the vertical separation system 203 so that when the vertical separation system 203 moves, the end effectors 210 move synchronously (or simultaneously, or at the same time) with the vertical separation system 203. For example, the end effectors 210 can be attached to the vertical separation system 203 via a sliding mechanism 205 installed on a side surface 203′ of the vertical separation system 203 so that the end effectors 210 each independently can move along the side surface 203′ of the vertical separation system 203 in the Z direction and locked (or unlocked) at various Z heights. As a result, Z heights and distances of the end effectors 210 can be adjusted depending on specific design needs and then locked at desirable Z heights and distances during operation. The sliding mechanism 205 can include, but is not limited to, a sliding track or rail system, a linear guide or slide, a telescopic mechanism, etc.

In some embodiments, the end effectors 210 are fixedly attached to the vertical separation system 203 in the XY plane. As a result, the end effectors 210 can move along the side surface 203′ in the Z direction, but not in the XY plane. In other embodiments, the end effectors 210 may move along the side surface 203′ in the Z direction as well as in the XY plane.

In some embodiments, the end effectors 210 are aligned with each other in the Z direction. Therefore when viewed in the Z direction from above, only a topmost end effector (e.g. 210a) can be seen. Additionally, the end effectors 210 can be removably attached to the vertical separation system 203 so that the number of the end effectors 210 can be adjusted.

The end effectors 210a, 210b, 210c and 210d are connected to the vertical separation system 203 via sliding structures 211a, 211b, 211c and 211d respectively. In the example of FIG. 2B, the end effector 210a can have a semi-circular shape so that when a wafer is loaded on the end effector 210a, a backside surface of the wafer can be exposed. The end effector 210a may optionally include at least one gas channel 215a that is configured to discharge a gas out of or generate vacuum on a top surface of the end effector 210a. For instance, a plurality of gas channels 215a can be installed along the semi-circular shape to hold the wafer by vacuum during operation. Because of the semi-circular shape, the end effector 210a can drop off a wafer on a chuck or pins, descend vertically to leave the wafer supported by the chuck/pins and exit a module without hitting (or colliding with) other components of the module. The end effector 210a can have various shapes and for example be in the form of a fork structure, a semi-circle structure, a pincette, or the like. In this example, the end effectors 210a-210d are aligned in the Z direction so only the end effector 210a is visible.

Still referring to FIG. 2B, the vertical separation system 203 can be slidably attached to the main body 201 in the Z direction and thus configured to move along the main body 201 in the Z direction. Similarly, the position of the vertical separation system 203 can be adjusted and then locked during operation. When the end effectors 210 and the vertical separation system 203 are locked, the end effectors 210, the vertical separation system 203 and the main body 201 can move synchronously. Alternatively or additionally, the main body 201 can self-rotate around its central axis. Accordingly, the vertical separation system 203 may be fixedly attached to the main body 201 in the XY plane.

In some embodiments, the controller 140 is coupled to the robot arm 220 and configured to control the vertical separation system 203 and the sliding structures 211a-211d so as to move the end effectors 210a-210d in the Z and Y directions respectively.

Note that FIGS. 2A and 2B are shown merely for illustrative purposes and are not limiting. For example, while only four end effectors (e.g. 210a, 210b, 210c and 210d) are shown, it should be understood that any plurality of end effectors 210 can be attached to the vertical separation system 203. Preferably, the robot arm 220 includes 2-30 end effectors 210, more preferably 3-20 end effectors 210, more preferably 4-10 end effectors 210. In addition, components of the transfer robot 200 (e.g. the main body 201 and the vertical separation system 203) can have various shapes.

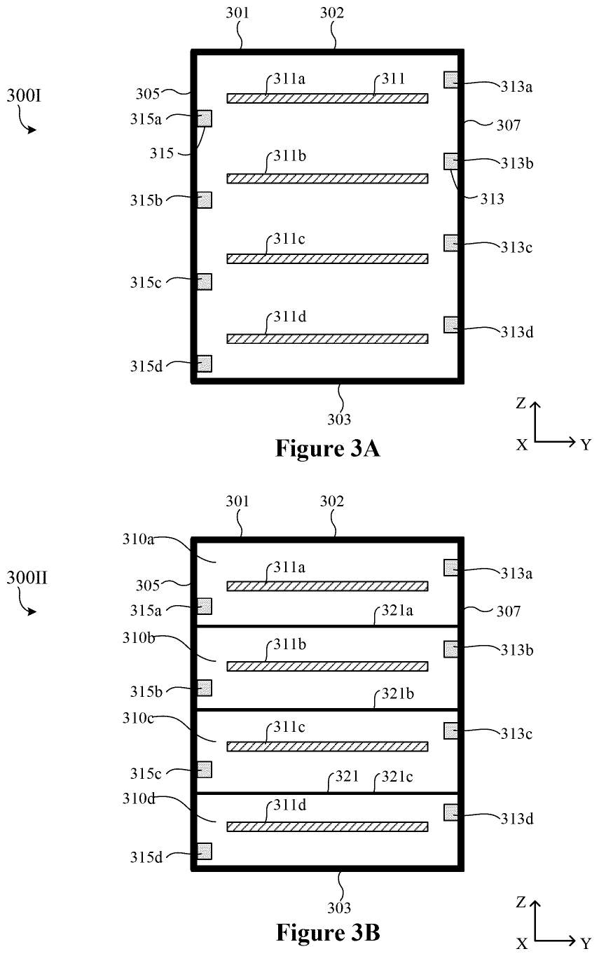

FIG. 3A shows a vertical cross-sectional view of a wafer module 300I in accordance with some embodiments of the present disclosure. Note that the wafer module 300I herein can represent embodiments of any one or more (or all) of the modules 131-139 and 121 in FIG. 1A.

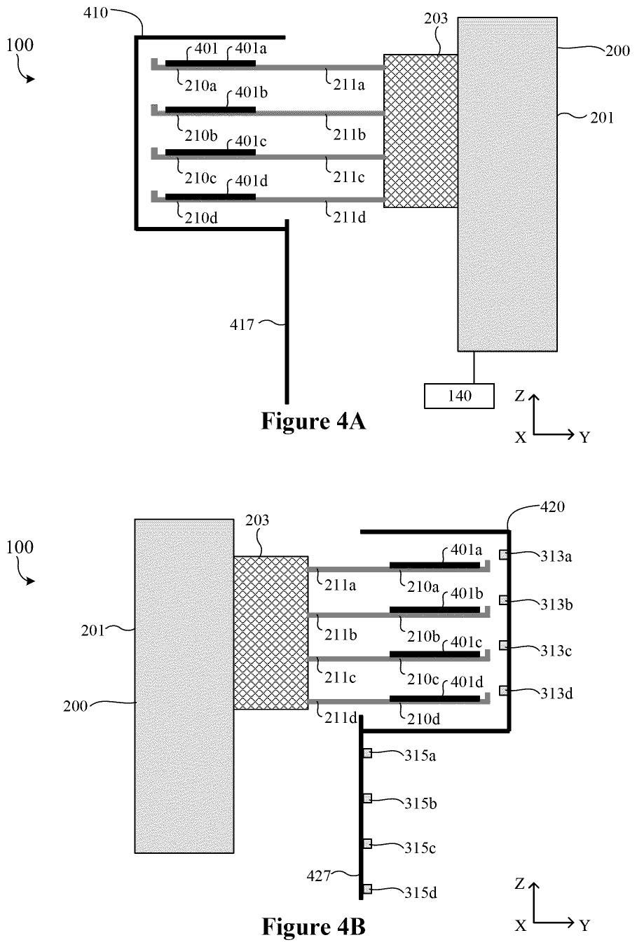

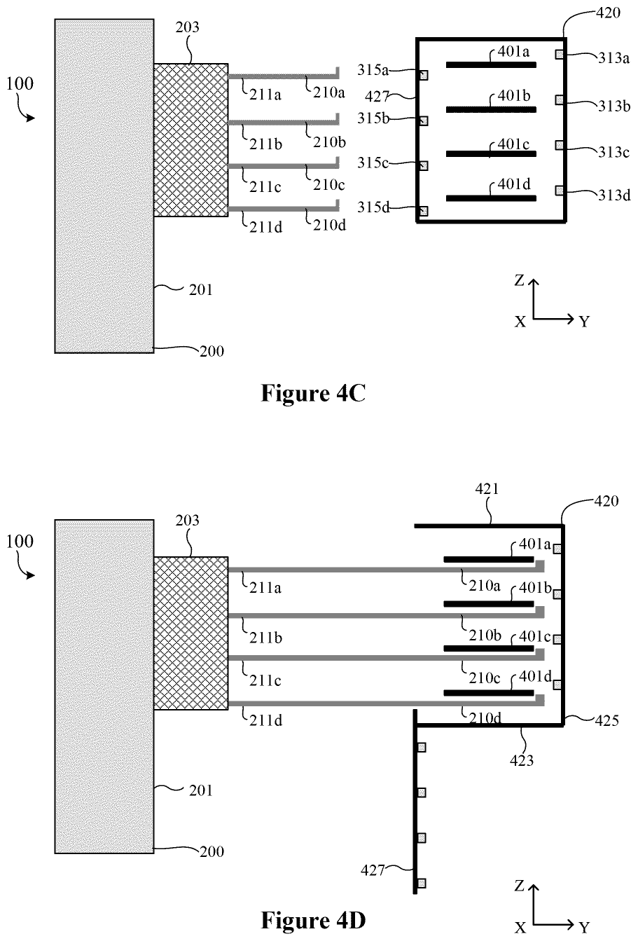

The wafer module 300I includes a chamber 301 having a top structure 302, a bottom structure 303, a first sidewall structure 305 and a second sidewall structure 307. One or more of the top structure 302, the bottom structure 303, the first sidewall structure 305 and the second sidewall structure 307 may include a gate (not shown) to open and close the chamber 301. The chamber 301 can include wafer mounting structures 311 (e.g. 311a, 311b, 311c and 311d) stacked over each other in the Z direction. The wafer mounting structures 311 can each receive a wafer (omitted herein for simplicity purposes; see e.g. 401a, 401b, 401c and 401d in FIGS. 4A-4D) thereon to be processed. The wafer mounting structures 311 can each independently be implemented by various structures including, but not limited to, a wafer carrier, a wafer chuck, a wafer plate, a wafer clamp, an electrostatic chuck, a vacuum chuck, a spin coater, a hot plate, etc. The wafer mounting structures 311 can each independently have various shapes, preferably a circular shape or a ring shape. In the case of a ring shape (e.g. a circle having a central hole therein), a backside surface of the wafer can be exposed and thus processed. The number of the wafer mounting structures 311 is not particularly limited and can for example be 2-30, preferably 3-20, preferably 4-10.

The wafer module 300I can also include one or more sensors 315 (e.g. 315a, 315b, 315c and 315d) in the chamber 301. The one or more sensors 315 may include, but are not limited to, a pressure sensor, a temperature sensor, a plasma sensor, a radio frequency (RF) sensor, a voltage and current (VI) sensor, a concentration sensor, an optical emission spectroscopy (OES) sensor, a reflectometer, or any combinations thereof. The number and position(s) of the one or more sensors 315 are not particularly limited. For instance, one or more pressure sensors and one or more temperature sensors can be positioned in various locations of the chamber 301, e.g. on an inner wall of the chamber 301, on a backside of each of the wafer mounting structures 311, above each of the wafer mounting structures 311, etc.

The wafer module 300I can further include one or more fluid inlets 313 (e.g. 313a, 313b, 313c and 313d). The one or more fluid inlets 313 can receive one or more fluids from fluid storage containers (not shown) and deliver the one or more fluids into the chamber 301. The number and position(s) of the one or more fluid inlets 313 are not particularly limited. For instance, the one or more fluid inlets 313 can be positioned in various locations of the chamber 301, e.g. on an inner wall of the chamber 301, on a backside of each of the wafer mounting structures 311, above each of the wafer mounting structures 311, etc.

As mentioned earlier, the wafer module 300I herein can represent some embodiments of any one or more (or all) of the modules 131-139 in FIG. 1A. For example, the wafer module 300I can represent some embodiments of the deposition module 132. Accordingly, the one or more fluid inlets 313 can receive vapors, and the wafer module 300I can function as a vapor deposition module such as a CVD module, an ALD module, etc. The wafer module 300I can also represent some embodiments of the etching module 137 and receive etching species, gaseous or liquid. The wafer module 300I can further represent some embodiments of the bake module 134, in which case the wafer mounting structures 311 can be in the form of hot plates. The one or more fluid inlets 313 may be used to deliver a non-reactive gas (e.g. an inert gas, nitrogen, etc.) or may alternatively not be needed.

In the example of FIG. 3A, the wafer mounting structures 311 are in the chamber 301 or rather in one common chamber. FIG. 3B shows a vertical cross-sectional view of a wafer module 300II in accordance with some embodiments of the present disclosure. The embodiment of the wafer module 300II is similar to the embodiment of the wafer module 300I. Note that similar or identical components are labeled with similar or identical numerals in the present disclosure unless specified otherwise. Similar or identical descriptions that have been provided will be omitted for simplicity purposes.

In FIG. 3B, the wafer module 300II includes one or more partition structures 321 (e.g. 321a, 321b and 321c) that divide the chamber 301 into separate sub-chambers e.g. 310a, 310b, 310c and 310d. As a result, each of the wafer mounting structures (e.g. 311a) can receive a respective wafer thereon to be processed in a separate sub-chamber (e.g. 310a), optionally with at least one separate sensor (e.g. 315a) and/or at least one separate fluid inlet (e.g. 313a).

The wafer module 300II herein can represent some embodiments of any one or more (or all) of the modules 131-139 in FIG. 1A. For example, the wafer module 300II can represent some embodiments of the coating module 133 and receive liquids such as photoresist solutions via the one or more fluid inlets 313. Accordingly, the wafer mounting structures 311 can be in the form of spin coaters, and the one or more fluid inlets 313 can be in the form of nozzles positioned above each of the spin coaters.

Still referring to FIGS. 3A and 3B, two or more of the wafer mounting structures 311 can each receive a respective wafer thereon, resulting in a plurality of wafers (omitted herein for simplicity purposes; see e.g. 401a, 401b, 401c and 401d in FIGS. 4A-4D) in the chamber 301. In some embodiments, the plurality of wafers can be processed using a common recipe under substantially identical experimental conditions. For example, a common CVD recipe can be executed in the wafer module 300I or 300II for four wafers on the wafer mounting structures 311a-311d, with the fluid inlets 313a-313d delivering identical vapor species at identical flow rates.

In some embodiments, the plurality of wafers can each independently be processed using a respective recipe. For example, when the wafer mounting structures 311a-311d in the wafer module 300I or 300II are hot plates, each hot plate can be set to a respective temperature. When the wafer mounting structures 311a-311d in the wafer module 300II are spin coaters, a different spin coating recipe can be executed in each of the sub-chambers 310a-310d.

Referring to FIGS. 1A, 1B, 2A, 2B, 3A and 3B, the second transfer arm 123 and/or the third transfer arm 125 can be implemented by embodiments of the transfer robot 200 while one or more of the modules 131-139 and 121 can each independently be implemented by embodiments of the wafer module 300I and/or 300II. During operation, the transfer robot 200 can be configured to transfer wafers from a first wafer module of the modules 131-139 and 121 to a second wafer module of the modules 131-139 and 121, as will be explained in detail in FIGS. 4A, 4B, 4C, and 4D which show vertical cross-sectional views of the apparatus 100 at various intermediate steps of a wafer process in accordance with some embodiments of the present disclosure.

In FIG. 4A, wafers 401 (e.g. 401a, 401b, 401c and 401d) are respectively positioned on first wafer mounting structures (omitted herein for simplicity purposes; see e.g. 311a-311d in FIGS. 3A-3B) of a first wafer module 410. The first wafer module 410 can be any one of the modules 131-139 and 121 and implemented by the wafer module 300I or 300II. In this example, the first wafer module 410 represents an embodiment of the wafer storage module, also referred to as the shelf unit 121, and is implemented by an embodiment of the wafer module 300I. A sidewall structure 417 of the first wafer module 410 can function as a gate. As shown, the gate is open. The transfer robot 200 can be used to unload each of the wafers 401a-401d from the first wafer mounting structures respectively onto the end effectors 210a-210d. In other words, the end effectors 210a-210d can be used to pick up the wafers 401a-401d. The controller 140 can be coupled to the transfer robot 200 and configured to execute the process described in FIG. 4A. While the controller 140 is omitted from FIGS. 4B-4D for simplicity purposes, it should be understood that the controller 140 can be used to execute the processes described in FIGS. 4B-4D.

In FIG. 4B, the transfer robot 200 is moved from the first wafer module 410 to a second wafer module 420. The second wafer module 420 can be any one of the modules 131-139 and 121 and implemented by the wafer module 300I or 300II. In this example, the second wafer module 420 represents an embodiment of the deposition module 132 and is implemented by an embodiment of the wafer module 300I. A sidewall structure 427 of the second wafer module 420 can function as a gate. As shown, the gate is open. The transfer robot 200 can be used to place the wafers 401a-401d respectively on second wafer mounting structures (omitted herein for simplicity purposes; see e.g. 311a-311d in FIGS. 3A-3B) of the second wafer module 420. Particularly, the second wafer mounting structures can include quartz carriers, and the second wafer module 420 can use a furnace-like design.

FIGS. 4A and 4B show a pick-and-place process where the wafers 401a-401d can be synchronously picked up from the first wafer module 410 and synchronously placed in the second wafer module 420 by the transfer robot 200. As explained earlier, the end effectors 210 and the vertical separation system 203 (and the main body 201) can move synchronously when locked. Herein, the main body 201 is moved from the first wafer module 410 to the second wafer module 420. Then, the main body 201 may self-rotate so that the vertical separation system 203 faces the second wafer module 420. The vertical separation system 203 can be unlocked and move along the main body 201 in the Z direction if needed. Similarly, the end effectors 210 can each independently be unlocked and move along the vertical separation system 203 in the Z direction if needed.

In FIG. 4C, the sliding structures 211 a-211d move in the Y direction towards the vertical separation system 203 so that the end effectors 210a-210d are moved out of the second wafer module 420, and the sidewall structure 427 (or the gate) is closed. A vapor deposition process can be executed. In this example, vapors of hexamethyldisilazane (HMDS) can be delivered via the fluid inlets 313a-313d to form an HMDS layer on top working surfaces of the wafers 401a-401d. Gas flow of HMDS vapors via the fluid inlets 313a-313d may be important and can be optimized by simulations and/or experiments. The HMDS layer can promote adhesion of a photoresist to the top working surfaces of the wafers 401a-401d in subsequent processes. When the second wafer mounting structures of the second wafer module 420 have a ring shape with a hole therein, an HMDS layer may also be formed on backside surfaces of the wafers 401a-401d, which can be beneficial to scanner chucking.

In FIG. 4D, the sidewall structure 427 (or the gate) is opened, after the vapor deposition process is completed. The sliding structures 211a-211d move in the Y direction away from the vertical separation system 203 so that the end effectors 210a-210d are used to pick up one or more of the wafers 410a-401d. As shown, the end effectors 210a-210d are respectively below the wafers 401a-401d in the Z direction. The vertical separation system 203 can move upwards in the Z direction so that the end effectors 210a-210d move upwards in the Z direction to respectively pick up the wafers 401a-401b.

Subsequent to the pick-up process in FIG. 4D, the transfer robot 200 may further transfer the wafers 401a-401d to one or more wafer modules for wafer processing or out of the apparatus 100. For instance, the transfer robot 200 may further transfer the wafers 401a-401d to a third wafer module. The third wafer module can represent an embodiment of the coating module 133 and be implemented by an embodiment of the wafer module 300II. A common spin coating recipe or two different spin coating recipes can be executed on the wafers 401a-401d. Then the transfer robot 200 may transfer the wafers 401a-401d to a fourth wafer module. The fourth wafer module can represent an embodiment of the bake module 134 and be implemented by an embodiment of the wafer module 300I or 300II. The wafers 401a-401d can be placed on hot plates for post-apply bake (PAB) at the same temperature or two different temperatures.

According to some aspects of the present disclosure, the number of the end effectors 210 is N. The number of the first wafer mounting structures (omitted for simplicity; see e.g. 311a-311d in FIGS. 3A-3B) in the first wafer module 410 is A. The number of the second wafer mounting structures (omitted for simplicity; see e.g. 311a-311d in FIGS. 3A-3B) in the second wafer module 420 is B. N is an integer of 2 or more. A is an integer of 2 or more. B is an integer of 2 or more. A is equal to or larger than N. B is equal to or larger than N.

In some embodiments, N is an integer of 2, 3, 4, 5, 6, 7, 8, 9, 10, etc. Preferably, N is 2-30, more preferably 3-20, more preferably 4-10. A can be a first multiple (e.g. 2, 3, 4, 5, 6, 7, 8, 9, 10, etc.) of N, and B can be a second multiple (e.g. 2, 3, 4, 5, 6, 7, 8, 9, 10, etc.) of N. For example, when N is 3, A and B can each independently be 3, 6, 9, 12, 15, 21, etc. When N is 4, A and B can each independently be 4, 8, 12, 16, 20, 24, etc.

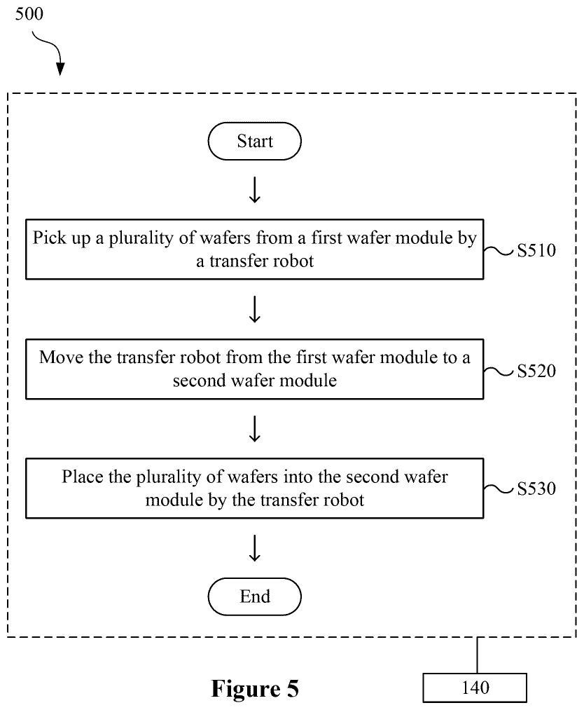

FIG. 5 shows a flow chart of a process 500, in accordance with some embodiments of the present disclosure. At step S510, a plurality of wafers (e.g. 401) are picked up from a first wafer module (e.g. 300I, 300II, 410 or the like) by a transfer robot (e.g. 200). At step S520, the transfer robot (e.g. 200) is moved from the first wafer module (e.g. 300I, 300II, 410 or the like) to a second wafer module (e.g. 300I, 300II, 420 or the like). At step S530, the plurality of wafers (e.g. 401) are placed into the second wafer module (e.g. 300I, 300II, 420 or the like) by the transfer robot (e.g. 200). As explained earlier, the plurality of wafers can be picked up synchronously at step S510, moved synchronously at step S520 and placed synchronously at step S530 by the transfer robot 200.

In some embodiments, the controller 140 may be coupled to various components of the process 500 to receive inputs from and provide outputs to the components. For example, the controller 140 can be configured to implement steps S510, S520 and/or S530. Of course, one or more functions of the controller 140 can also be manually accomplished.

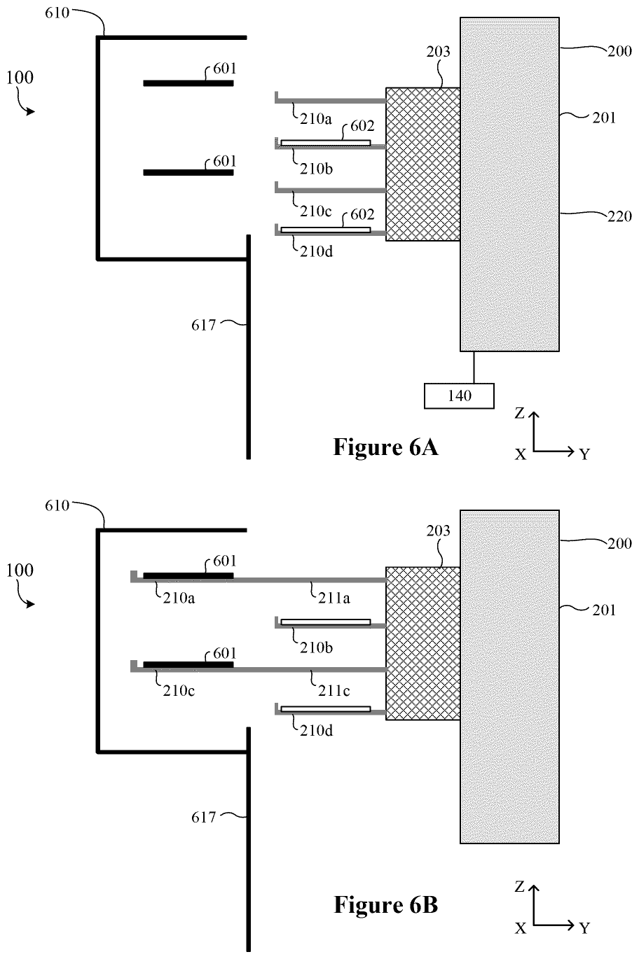

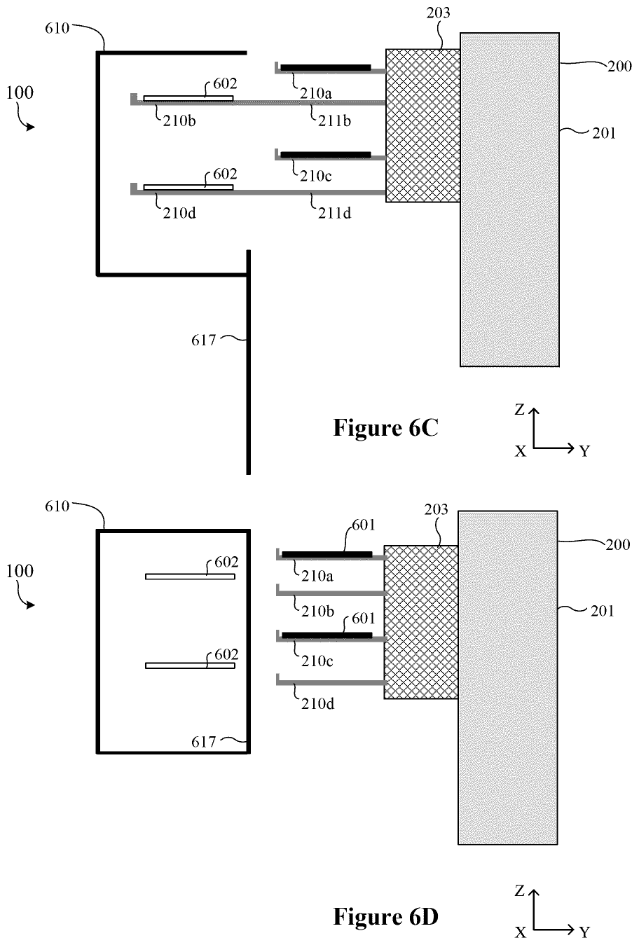

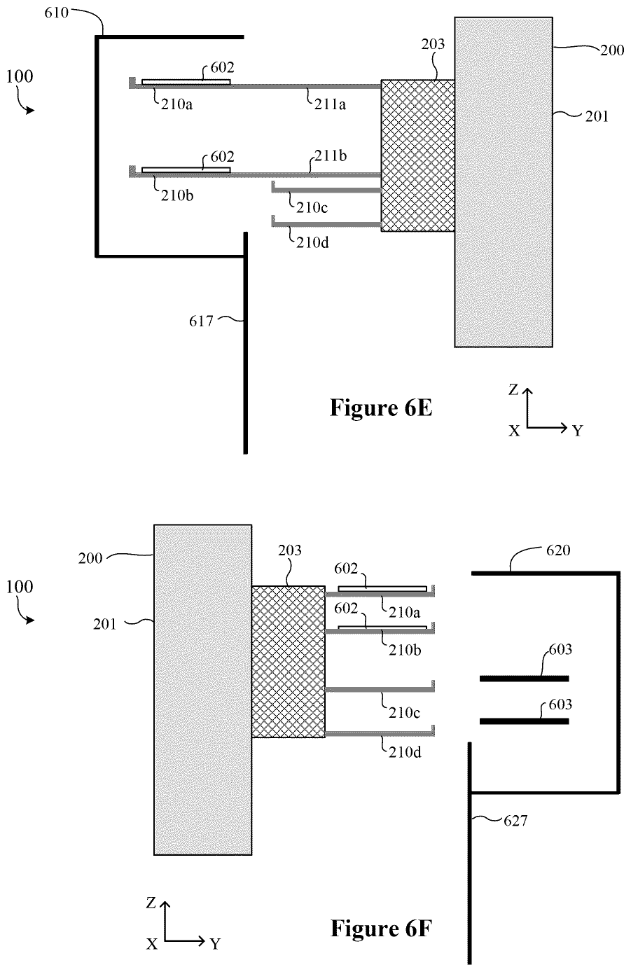

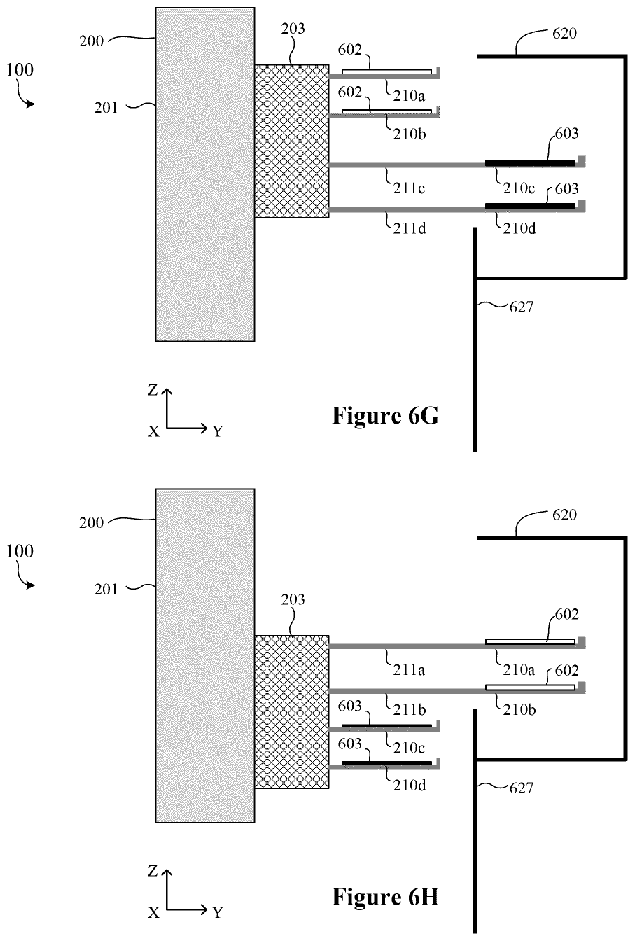

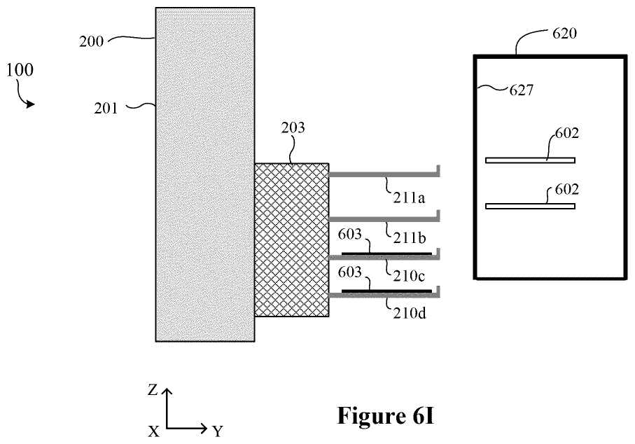

FIGS. 6A, 6B, 6C, 6D, 6E, 6F, 6G, 6H and 6I show vertical cross-sectional views of the apparatus 100 at various intermediate steps of a wafer process in accordance with some embodiments of the present disclosure. In FIG. 6A, a first group of wafers 601 are positioned on first wafer mounting structures (omitted herein for simplicity purposes; see e.g. 311a-311d in FIGS. 3A-3B) of a first wafer module 610. The first wafer module 610 can be any one of the modules 131-139 and 121 and implemented by the wafer module 300I or 300II. A sidewall structure 617 of the first wafer module 610 can function as a gate. As shown, the gate is open. In this example, the end effectors 210a and 210c of the robot arm 220 of the transfer robot 200 are aligned with the first group of wafers 604 or the first wafer mounting structures in the Z direction. A second group of wafers 602 are respectively placed on the end effectors 210b and 210d. In some embodiments, the first group of wafers 601 have already been subjected to a wafer process (e.g. film deposition, spin coating, etching, baking, etc.) in the first wafer module 610 before the sidewall structure 617 is opened. The controller 140 can be coupled to the transfer robot 200 and configured to execute the process described in FIG. 6A. While the controller 140 is omitted from FIGS. 6B-6I for simplicity purposes, it should be understood that the controller 140 can be used to execute the processes described in FIGS. 6B-6I.

In FIG. 6B, the transfer robot 200 can be used to unload the first group of wafers 601 from the first wafer mounting structures respectively onto the end effectors 210a and 210c. In other words, pincette structures of the end effectors 210a and 210c can be used to pick up the first group of wafers 601.

Referring to FIGS. 6A and 6B, in some embodiments, the end effectors 210a and 210c may be positioned below (e.g. slightly below) the first group of wafers 601 in the Z direction in FIG. 6A. A vertical distance between the end effectors 210a and 210c in the Z direction is equal to a vertical distance between the first group of wafers 601 (or the first wafer mounting structures). The sliding structures 211a and 211c move in the Y direction so that the end effectors 210a and 210c move towards the first group of wafers 601. Then, the vertical separation system 203 can move upwards in the Z direction so that the end effectors 210a and 210c simultaneously collect or pick up the first group of wafers 601.

In FIG. 6C, the sliding structures 211a and 211c move in the Y direction so that the end effectors 210a and 210c move towards the vertical separation system 203. A vertical distance between the end effectors 210b and 210d in the Z direction is equal to a vertical distance between the first wafer mounting structures. The vertical separation system 203 moves upwards in the Z direction so that the end effectors 210b and 210d are respectively above (e.g. slightly above) the first wafer mounting structures. The sliding structures 211b and 211d move in the Y direction so that the end effectors 210b and 210d move towards the first wafer mounting structures (or away from the vertical separation system 203). The vertical separation system 203 moves downwards in the Z direction so that the end effectors 210b and 210d simultaneously deposit or drop off the second group of wafers 602 onto the first wafer mounting structures.

In FIG. 6D, the sliding structures 211b and 211d move in the Y direction so that the end effectors 210b and 210d move towards the vertical separation system 203. The sidewall structure 617 of the first wafer module 610 is closed. Then, a first wafer process (e.g. film deposition, spin coating, etching, baking, etc.) is executed on the second group of wafers 602. The first group of wafers 601 can go through further wafer processing or moved out of the apparatus 100. As a result, the end effectors 210a and 210c can become vacant.

In FIG. 6E, the end effectors 210a and 210b are used to pick up the second group of wafers 602 from the first wafer module 610 after the first wafer process is finished. Note that any two of the end effectors 210a-210d can be used to pick up the second group of wafers 602. The end effectors 210a and 210b are shown herein as one example merely for illustrative purposes.

In FIG. 6F, the transfer robot 200 is moved from the first wafer module 610 to a second wafer module 620. The Z heights of the end effectors 210c and 210d are adjusted to align with, or below (e.g. slightly below) in the Z direction, a third group of wafers 603 placed on second wafer mounting structures (omitted herein for simplicity purposes; see e.g. 311a-311d in FIGS. 3A-3B) in the second wafer module 620. A vertical distance between the end effectors 210c and 210d in the Z direction is equal to a vertical distance between the third group of wafers 603 (or the second wafer mounting structures). Preferably, the Z heights of the end effectors 210a-210d are adjusted while the transfer robot 200 is moved from the first wafer module 610 to the second wafer module 620. While such simultaneous movements are time-efficient, they are not always necessary. For instance, the Z heights of the end effectors 210a-210d can be adjusted after the transfer robot 200 is moved from the first wafer module 610 to the second wafer module 620.

The second wafer module 620 can be any one of the modules 131-139 and 121 and implemented by the wafer module 300I or 300II. A sidewall structure 627 of the second wafer module 620 can function as a gate. As shown, the gate is open. In some embodiments, the third group of wafers 603 have already been subjected to a wafer process (e.g. film deposition, spin coating, etching, baking, etc.) in the second wafer module 620 before the sidewall structure 627 is opened.

In FIG. 6G, the end effectors 210c and 210d are used to pick up the third group of wafers 603. For example, the sliding structures 211c and 211d can move in the Y direction so that the end effectors 210c and 210d move towards the third group of wafers 603. Then, the vertical separation system 203 can move upwards in the Z direction so that the end effectors 210c and 210d simultaneously collect or pick up the third group of wafers 603.

In FIG. 6H, the sliding structures 211c and 211d move in the Y direction so that the end effectors 210c and 210d move towards the vertical separation system 203. The end effectors 210a-210d are moved in the Z direction by the vertical separation system 203 so that the end effectors 210a and 210b are aligned with or above (e.g. slightly above) the aforementioned second wafer mounting structures in the Z direction. A vertical distance between the end effectors 210a and 210b in the Z direction is equal to a vertical distance between the second wafer mounting structures. The sliding structures 211a and 211b move in the Y direction so that the end effectors 210a and 210b move towards the second wafer mounting structures. Then, the vertical separation system 203 can move downwards in the Z direction so that the end effectors 210a and 210b simultaneously deposit or drop off the third group of wafers 603 onto the second wafer mounting structures.

In FIG. 6I, the sliding structures 211a and 211b move in the Y direction so that the end effectors 210a and 210b move towards the vertical separation system 203. The sidewall structure 627 of the second wafer module 620 is closed. Then, a second wafer process (e.g. film deposition, spin coating, etching, baking, etc.) is executed on the second group of wafers 602. The first wafer process executed in the first wafer module 610 and the second wafer process executed in the second wafer module 620 may represent any two consecutive processes of lithography. Additionally, the third group of wafers 603 can go through further wafer processing or moved out of the apparatus 100.

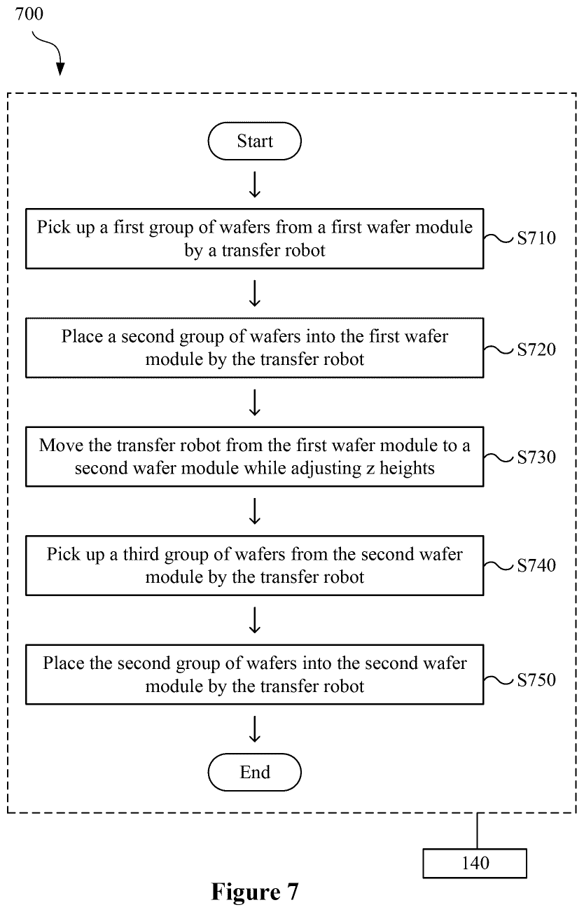

FIG. 7 shows a flow chart of a process 700 for manufacturing a semiconductor device, in accordance with some embodiments of the present disclosure. At step S710, a first group of wafers (e.g. 601) are picked up from a first wafer module (e.g. 300I, 300II, 610 or the like) by a transfer robot (e.g. 200). At step S720, a second group of wafers (e.g. 602) are placed into the first wafer module by the transfer robot. At step S730, the transfer robot is moved from the first wafer module to a second wafer module (e.g. 300I, 300II, 620 or the like). Z heights of end effectors (e.g. 210a-210d) of the transfer robot can be adjusted. As explained earlier, moving the transfer robot and adjusting the Z heights of the arm structures can be done simultaneously. At step S740, a third group of wafers (e.g. 603) are picked up from the second wafer module by the transfer robot. At step S750, the second group of wafers are placed into the second wafer module by the transfer robot.

In some embodiments, the controller 140 may be coupled to various components of the process 700 to receive inputs from and provide outputs to the components. For example, the controller 140 can be configured to implement steps S710, S720, S730, S740 and/or S750. Of course, one or more functions of the controller 140 can also be manually accomplished.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments. “Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A robot transfer system for transferring wafers within a wafer processing system, the robot transfer system comprising:
a robot arm adapted for rotation within the wafer processing system and adapted for movement in multiple directions within the wafer processing system, the robot arm comprising multiple end effectors positioned vertically over each other, each end effector adapted to collect, hold and deposit a respective wafer for transfer within the wafer processing system;
a vertical separation system adapted to move the end effectors of the robot arm vertically relative to each other to increase and decrease a vertical separation of the end effectors relative to each other; and
a controller configured to control the robot arm and control the vertical separation system, wherein the controller is configured to move the robot arm to a first location for collecting multiple wafers separated vertically at a first spacing, the controller is configured to cause the vertical separation system to position the multiple end effectors to match a first vertical separation of the multiple wafers at the first location and simultaneously collect the multiple wafers at the first location, the controller is further configured to move the multiple wafers to a second location for depositing the multiple wafers such that the multiple wafers are vertically separated relative to each other at a second spacing that is different than the first spacing, and the controller is configured to cause the vertical separation system to position the multiple end effectors to match a second vertical separation of the multiple wafers at the second location and cause the robot arm to simultaneously deposit the multiple wafers at the second location.

2. The robot transfer system of claim 1, wherein:
the controller is configured to cause the vertical separation system to position the multiple end effectors to match the second vertical separation of the multiple wafers simultaneously while moving the multiple wafers from the first location to the second location.

3. The robot transfer system of claim 1, wherein:
the robot arm further comprises multiple sliding structures, each sliding structure connecting a respective end effector to the vertical separation system and adapted for horizontal movement to adjust a respective horizontal distance between the respective end effector and the vertical separation system.

4. The robot transfer system of claim 3, wherein:
the controller is configured to horizontally move the multiple sliding structures to move the multiple end effectors towards the multiple wafers at the first location, vertically raise the multiple end effectors to simultaneously pick up the multiple wafers and horizontally move the multiple sliding structures to move the multiple end effectors towards the vertical separation system.

5. The robot transfer system of claim 3, wherein:
the controller is configured to horizontally move the multiple sliding structures to move the multiple end effectors towards the second location, vertically lower the multiple end effectors to simultaneously drop off the multiple wafers and horizontally move the multiple sliding structures to move the multiple end effectors towards the vertical separation system.

6. The robot transfer system of claim 1, wherein:
the robot arm comprises a main body, and
the vertical separation system is attached to a side surface of the main body and adapted for vertical movement along the side surface of the main body.

7. The robot transfer system of claim 6, wherein:
the multiple end effectors are attached to the vertical separation system so that when the vertical separation system moves vertically along the side surface of the main body, the multiple end effectors simultaneously move vertically.

8. The robot transfer system of claim 1, wherein:
after causing the vertical separation system to position the multiple end effectors to match the second vertical separation of the multiple wafers, the controller is configured to lock the multiple end effectors to the vertical separation system.

9. The robot transfer system of claim 8, wherein:
the controller is configured to simultaneously move the multiple end effectors vertically by moving the vertical separation system vertically when the multiple end effectors are locked to the vertical separation system.

10. The robot transfer system of claim 8, wherein:
the controller is configured to simultaneously collect or deposit the multiple wafers by moving the vertical separation system vertically when the multiple end effectors are locked to the vertical separation system.

11. The robot transfer system of claim 1, wherein:
the multiple end effectors are aligned with each other vertically.

12. The robot transfer system of claim 1, wherein:
the multiple end effectors include at least one of a fork structure, a semi-circle structure or a pincette.

13. The robot transfer system of claim 1, wherein:
the multiple end effectors each comprises a respective gas channel configured to discharge a gas or generate vacuum.

14. The robot transfer system of claim 1, wherein:
the vertical separation system includes at least one of a sliding track, a linear guide or a telescopic mechanism.

15. The wafer processing system of claim 1, comprising:
the robot transfer system of claim 1; and
at least one wafer module comprising wafer mounting structures stacked vertically at the second location.

16. The wafer processing system of claim 15, wherein:
the at least one wafer module includes at least one selected from the group consisting of a storage module, a metrology module, a deposition module, a coating module, a bake module, an imaging module, a development module, an etching module, a cleaning module and an inspection module.

17. The wafer processing system of claim 16, wherein:
the at least one wafer module comprises a deposition module including a deposition chamber and gas inlets stacked vertically and configured to deliver vapors into the deposition chamber.

18. The wafer processing system of claim 17, further comprising:
a coating module including spin coaters stacked vertically; and
a bake module including hot plates stacked vertically.

19. The wafer processing system of claim 15, wherein:
the number of the multiple end effectors is N, the number of the wafer mounting structures is B,
N is an integer of 2 or more,
B is an integer of 2 or more, and
N is equal to or larger than B.

20. The wafer processing system of claim 19, wherein:
N is a multiple of B.
